(19) United States
(12) Patent Application Publication
(10) Pub. No.: US 2009/0029033 A1
(43) Pub. Date: Jan. 29, 2009

(54) Method of manufacturing thin-film based PV modules

(76) Inventor: Joseph Chou, Hong Kong (HK)

Correspondence Address: DAVID AND RAYMOND PATENT FIRM, 108 N. YNEZ AVE., SUITE 128, MONTEREY PARK, CA, 91754, US

(21) Appl. No.: 11/881,570

(22) Filed: Jul. 27, 2007

(51) Int. Cl. B05D 5/12

(52) U.S. Cl. 427/74

(57) ABSTRACT

A method of manufacturing thin-film-base PV module includes the steps of slidably loading one or more glass substrates in a standing manner into a stationary deposition chamber in a fully automatic manner by guiding the bottom peripheral edges of the glass substrates along transferring tracks; administering the glass substrates through a deposition process within the deposition chamber to form the PV modules; and slidably unloading the PV modules from the deposition chamber in a fully automatic manner by guiding the bottom peripheral edges of the PV modules along the transferring tracks.

### BACKGROUND OF THE PRESENT INVENTION

1. Field of Invention

The present invention relates to a PV module, and more particularly to a method of manufacturing thin-film-based PV modules, wherein a plurality of spaced apart glass substrates are vertically fed into a deposition chamber of a stationary deposition room in a fully automatic manner so as to minimize the labor cost of the PV module while being time effective.

2. Description of Related Arts

Searchers indicate that the world might be heading for a global energy crisis by rapidly increasing energy prices, especially crude oil and natural gas, and by declining oil endowment. In order to ensure there is enough energy in the future, alternative energy sources must be developed. For example, wind power is one of the alternative energy sources to approach the cost efficiency of oil and gas. Solar electric system is considered as one of the best environment friendly energy to minimize the effects of the future crisis.

Solar electric system is also known as Photovoltaic (PV) system in which photovoltaic technology was developed in the early 1950s. Accordingly, photovoltaic technology makes use of the abundant energy in the sun and has numerous environmental benefits. It can be used in wide range of products from small consumer products to large commercial solar electric systems.

Photovoltaic system comprises solar cells to convert solar energy into electric energy, wherein each of the solar cells comprises a plurality of solar panels interconnected with each other for collecting solar energy. Each of the solar panels, which also refers to a photovoltaic module, is made of a tempered glass as the glass substrate treated with the deposition process. The cost of the solar panel made of glass is relatively inexpensive in comparison with conventional substrate. However, the method of manufacturing the photovoltaic module is relatively complicated, time consuming, and in high cost.

A conventional method of manufacturing the photovoltaic module requires a relatively high labor cost that operators must manually feed the glass substrates one-by-one into a deposition chamber for deposition process. Accordingly, each of the glass substrates is a glass panel having four peripheral edges and two opposed glass surfaces. The operators must stack each of the glass substrates from a horizontal orientation to a vertical orientation such that the vertical glass substrates are spacedly supported before the glass substrates are loaded in the deposition chamber. Since each of the glass substrates is supported at the vertical orientation, the depositing material can be effectively deposited on the glass surface of each of the glass substrates. In other words, the glass substrate cannot be laid flat in the deposition chamber during the deposition process.

The first major problem of the manufacturing process is how to vertically and spacedly support the glass substrates in the deposition chamber without contacting the glass surface. Since the depositing material is deposited on the glass surface of the glass substrate, the contact of the glass surface of the glass substrate might cause the imperfection of the photovoltaic module. In other words, the glass substrate can only be supported at the peripheral edge thereof.

Another major problem of the manufacturing process is that the RF electrode is located out of the deposition chamber. Accordingly, amorphous silicon (a-Si) is loaded at the RF electrode, wherein the RF electrode is coupled with the glass substrate to transfer into the pre-heat oven such that the RF electrode and the glass substrate are pre-heated at the same time before the deposition process.

Another major problem of the manufacturing process is how to load the glass substrates in the deposition chamber. Accordingly, there are thirty-six to forty-eight glass substrates loaded in the deposition chamber during each deposition process. It is time consuming that the operators must feed the glass substrates one-by-one into the deposition chamber. In fact, the overall weight of the glass substrates with the RF electrodes at each load is approximately 350 kg such that the transportation of the glass substrates is extremely difficult. Most importantly, the glass substrates must be supported at the vertical orientation such that any unwanted vibration during the transportation might break the glass substrates in the deposition chamber. In addition, when the glass substrates are moved to the deposition chamber one-by-one, particles may accidentally drop on the glass surface so as to cause the imperfection of the photovoltaic module.

Another problem of the manufacturing process is that the glass substrates must be cleaned in a dust free manner and pre-heated at a predetermined temperature before the glass substrates are loaded in the deposition chamber. Accordingly, the spaced apart glass substrates are manually laid flat for cleaning process and then the glass substrates are sent to the pre-heat chamber for pre-heating process. Therefore, the operators will need to stack each of the glass substrates from the horizontal orientation to the vertical orientation in the deposition chamber. It is worth to mention that when the glass substrates are transported from the pre-heat chamber to the deposition chamber, the temperature of each of the glass substrates will drop due to the difference of the ambient temperature. In other words, during the transportation, the pre-heat energy of the glass substrate will lose and particles may accidentally drop on the glass surface to cause the imperfection of the photovoltaic module.

Furthermore, after the deposition process, the glass substrates are manually unloaded from the deposition chamber on-by-one to the cooling chamber. Therefore, the entire manufacturing line starting from cleaning to cooling steps is manual controlled by the operators. Therefore, the labor cost of the photovoltaic module is extremely high and the manufacturing process is very time consuming.

### SUMMARY OF THE PRESENT INVENTION

A main object of the present invention is to provide a method of manufacturing thin-film-based PV modules, wherein the manufacturing line of the photovoltaic module is fully automatic so as to reduce the labor cost of the photovoltaic module.

Another object of the present invention is to provide a method of manufacturing thin-film-base PV modules, wherein the spaced apart glass substrates are vertically fed into a deposition chamber of a stationary deposition room in a fully automatic manner so as to minimize the labor cost of the PV module while being time effective. In other words, the glass substrates are automatically sent from one chamber to another chamber to minimize the transportation time thereof.

Another object of the present invention is to provide a method of manufacturing thin-film-base PV modules, wherein the spaced apart glass substrates are vertically fed into the deposition chamber in a stable manner so as to prevent the glass substrates from being broken accidentally.

Another object of the present invention is to provide a method of manufacturing thin-film-base PV modules, wherein the stationary deposition room has a door for the glass substrates loading to the deposition chamber for deposition process and for the glass substrates unloading from the deposition chamber after the deposition process, so as to minimize the space occupied by the stationary deposition room and to speed up the entire deposition process.

Another object of the present invention is to provide a method of manufacturing thin-film-base PV modules, wherein each of the glass substrates is vertically supported at the peripheral edge thereof to be fed into the deposition chamber so as to maximize the glass surface of each of the glass substrates for deposition process.

Another object of the present invention is to provide a method of manufacturing thin-film-base PV modules, wherein when the glass substrates are loaded in the deposition chamber, the glass substrates are automatically aligned with the RF electrodes respectively for depositing the depositing material on the glass surfaces.

Another object of the present invention is to provide a method of manufacturing thin-film-base PV modules, wherein the RF electrode is stationary supported within the deposition chamber to align with the glass substrate when the glass substrate is fed therein. Therefore, it is hassle free to move the RF electrode with the glass substrate together for pre-heating in comparison with the conventional manufacturing method.

Another object of the present invention is to provide a method of manufacturing thin-film-base PV modules, wherein the deposition chamber has a heat source to maintain RF electrode at the optimized temperature for deposition process so as to reduce the time for pre-heating the RF electrode.

Accordingly, in order to accomplish the above mentioned objects, the present invention provides a method of manufacturing thin-film-base PV module, comprising the steps of:

(a) slidably loading at least a vertical glass substrate into a stationary deposition chamber in a fully automatic manner by guiding the bottom peripheral edge of the vertical glass substrate along a transferring track;

(b) administering the glass substrate through a deposition process within the deposition chamber to form the PV module; and

(d) slidably unloading the PV module from the deposition chamber in a fully automatic manner by guiding the bottom peripheral edge of the PV module along the transferring track.

These and other objectives, features, and advantages of the present invention will become apparent from the following detailed description, the accompanying drawings, and the appended claims.

### BRIEF DESCRIPTION OF THE DRAWINGS

FIG. 1 is a perspective view of a deposition system according to a preferred embodiment of the present invention.

FIG. 2 is a flow diagram of a method of manufacturing thin-film-base PV module through the deposition system according the above preferred embodiment of the present invention.

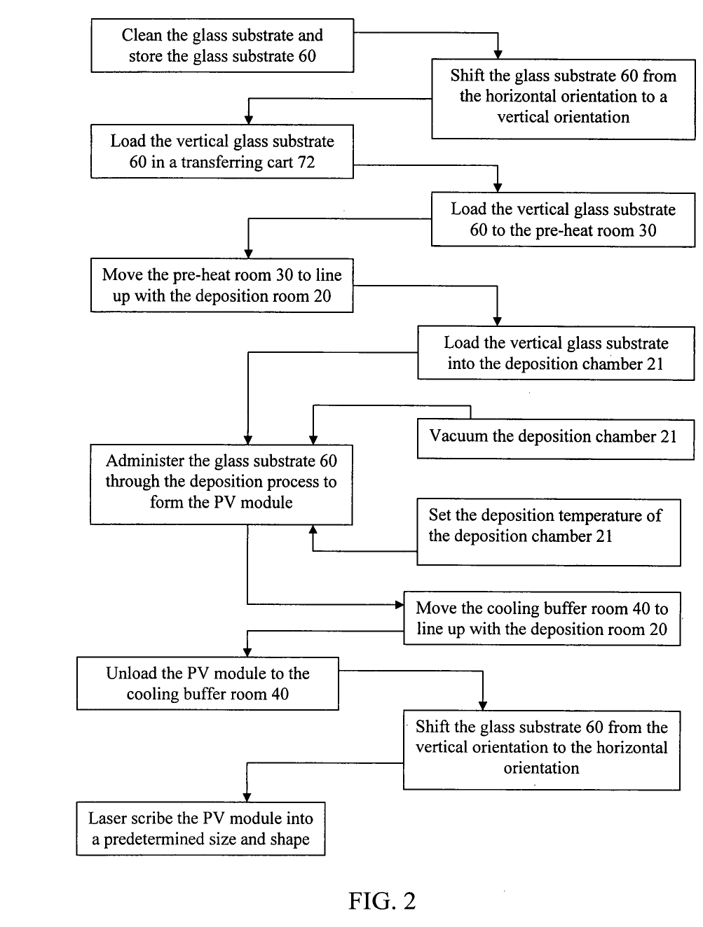

FIG. 3 is a perspective view of a robot loading device of the deposition system according the above preferred embodiment of the present invention.

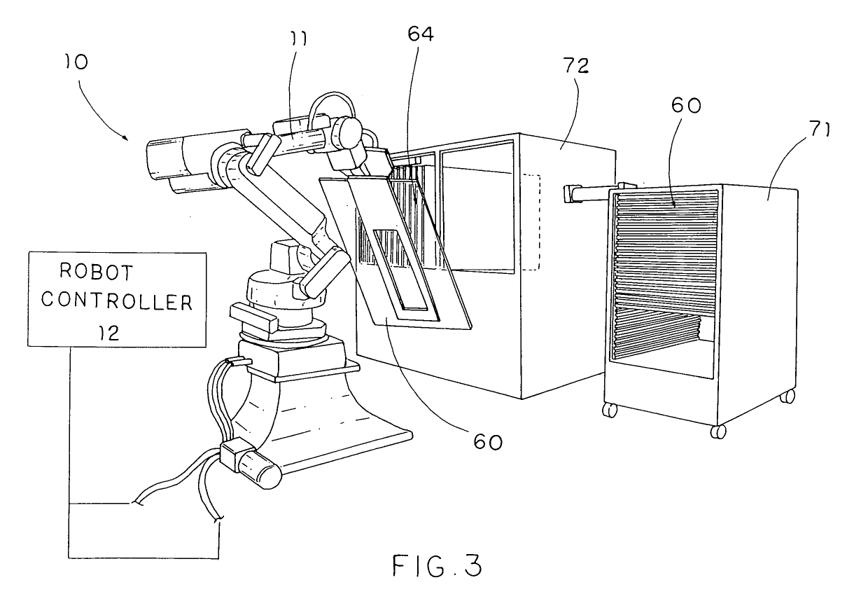

FIG. 4 is a perspective view of a substrate transferring device of the deposition system according the above preferred embodiment of the present invention.

FIG. 5 is a partially sectional view of the substrate transferring device of the deposition system according the above preferred embodiment of the present invention.

FIG. 6 is a front view of the transferring track of the substrate transferring device of the deposition system according the above preferred embodiment of the present invention.

FIG. 7 is a block diagram illustrating the manufacturing process of the PV module according to the above preferred embodiment of the present invention.

FIG. 8 is a schematic diagram illustrating the glass substrate being guided via a feeding guider with respect to the transferring track according to the above preferred embodiment of the present invention.

FIG. 9 is a schematic diagram illustrating the pivot arm pushing the glass substrate according to the above preferred embodiment of the present invention.

FIG. 10 is a schematic diagram illustrating the PV module being transferred from the deposition room to the cooling buffer room according to the above preferred embodiment of the present invention.

### DETAILED DESCRIPTION OF THE PREFERRED EMBODIMENT

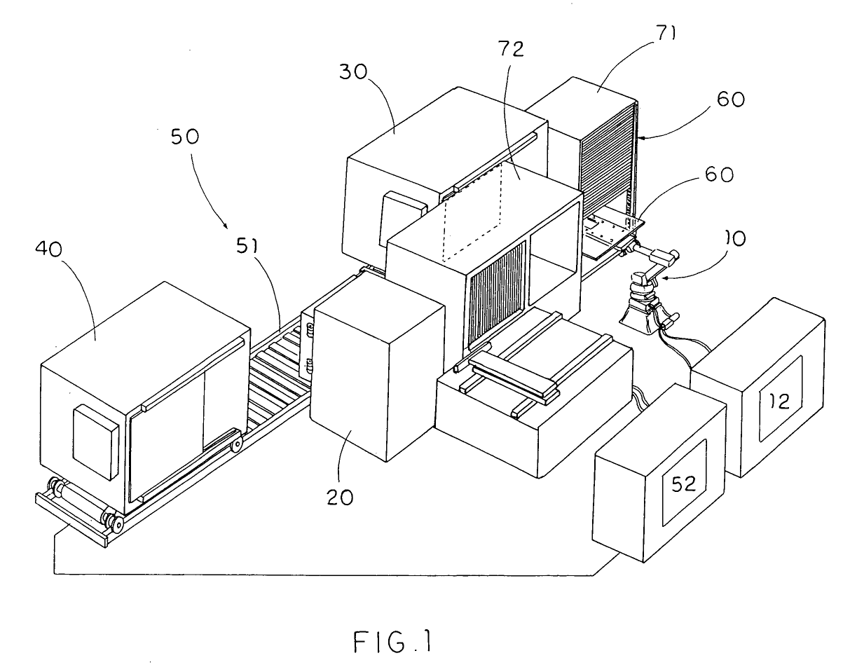

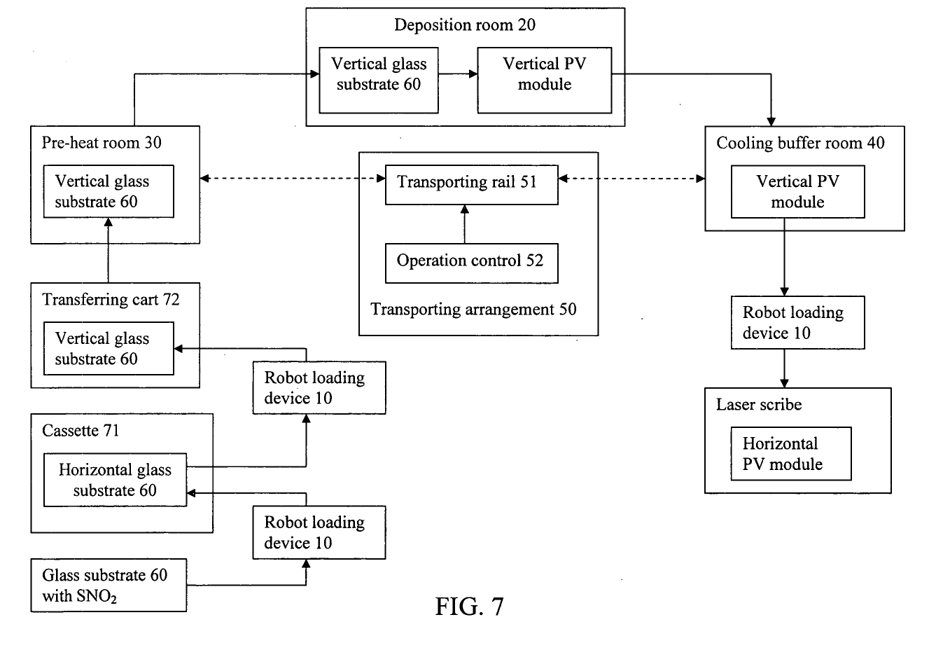

Referring to FIGS. 1 and 7 of the drawings, a deposition system according to a preferred embodiment of the present invention, wherein the deposition system comprises a robot loading device 10, a stationary deposition room 20, a pre-heat room 30, and a cooling buffer room 40, and a transporting arrangement 50 controllably transferring the pre-heat room 30 and a cooling buffer room 40 to align with the deposition room 20.

Accordingly, the transporting arrangement 50 comprises a transporting rail 51 and an operation control 52 controlling each of the pre-heat room 30 and a cooling buffer room 40 to slide along the transporting rail 51 so as to controllably transport each of the pre-heat room 30 and a cooling buffer room 40 to alignedly communicate with the deposition room 20. As shown in FIG. 1 the deposition room 20 is located between the pre-heat room 30 and the cooling buffer room 40 at a position adjacent to the transporting rail 51 such that each of the pre-heat room 30 and a cooling buffer room 40 is controllably moved to line up with the deposition room 20.

According to the preferred embodiment, the deposition system of the present invention is used for manufacturing a thin-film-base PV module 60′ from a glass substrate 60 through the deposition process. Accordingly, the glass substrate 60, preferably having a rectangular shape, has a bottom peripheral edge 61, a top peripheral edge 62, two side peripheral edges 63, and two glass surfaces 64.

The present invention further provides a process of manufacturing thin-film-base PV module 60′ through the deposition system, comprising the following steps.

(1) Clean the glass substrate 60 in a dust free manner and store the glass substrate 60 in a cassette 71 in a horizontal orientation.

(2) Automatically shift the glass substrate 60 from the lying orientation to a standing orientation via the robot loading device 10. Preferably, the glass substrate 60 is shifted from the horizontal orientation to the vertical orientation.

(3) Automatically load the glass substrate 60 at the vertical orientation in a transferring cart 72 such that the glass substrate 60 is supportively retained at the vertical orientation.

(4) Slidably load the glass substrate at the vertical orientation from the transferring cart 72 to the pre-heat room 30 such that the glass substrate 60 is pre-heated in the pre-heat room 30 at an optimized temperature.

(5) Controllably move the pre-heat room 30 along the transporting rail 51 to align with the deposition room 20.

(6) Slidably load the glass substrate at the vertical orientation into the deposition chamber 21 of the deposition room 20 in a fully automatic manner.

(7) Administer the glass substrate 60 at the vertical orientation through the deposition process within the deposition chamber 21 to form the PV module 60′.

(8) Controllably move the cooling buffer room 40 along the transporting rail 51 to align with the deposition room 20.

(9) Slidably unload the PV module 60′ from the deposition chamber 21 in a fully automatic manner to the cooling buffer room 40.

In step (1), the glass substrate 60 is laid flat in a horizontal orientation and is supported by the cassette 71. Accordingly, the cassette 71 is adapted to spacedly support two or more glass substrates 60 at the horizontal orientation such that the glass substrates 60 at the horizontal orientation are cleaned through the cleaning process. It is worth to mention that the glass substrate 60 is coated with SNO₂ before the glass substrate 60 is sent for cleaning purpose.

The robot loading device 10 comprises a robot loading arm 11 and a robot controller 12 controlling the robot loading arm I1 to automatically lift up the glass substrate 60 from the cassette 71 and to automatically shift the glass substrate 60 from the horizontal orientation to the vertical orientation in the step (2). Accordingly, the glass substrate 60 is full-automatically transferred from the cassette 71 to the transferring cart 72 by the operation of the robot controller 12 such that the operator does not move the glass substrate 60 by hand to prevent any hand-contact on the glass surface 64 so as to minimize any, particle drop on the glass surface 64.

In step (3), the glass substrate 60 at the vertical orientation is automatically loaded in a transferring cart 72 through a substrate transferring device 80. Accordingly, the transferring cart 72 is arranged to supportively retain two or more spaced apart glass substrates 60 at the vertical orientation.

In step (4), the transferring cart 72 is aligned with the accessing door of the pre-heat room 30 in order to slidably load the glass substrate 60 at the vertical orientation from the transferring cart 72 to the pre-heat room 30 through the accessing door. Accordingly, when two or more glass substrates 60 are loaded at the transferring cart 72, all the glass substrates 60 are transferred into the pre-heat room 30 at the same time. Once the glass substrate 60 is vertically supported in the pre-heat room 30, the glass substrate 60 is pre-heated until the glass substrate 60 reaches the optimized temperature.

Once the glass substrate 60 is pre-heated, the pre-heat room 30 is moved along the transporting rail 51 to line up with the deposition room 20 in step (6). Accordingly, the deposition room 20 is a stationary manner while the pre-heat room 30 is moved to align with the deposition room 20 in a door-to-door manner. In addition, after the step (6), the pre-heat room 30 is moved back to its original position for loading the next glass substrate 60 to reduce the manufacturing time of the process.

In step (7), the glass substrate 60 at the vertical orientation is supported in the deposition chamber 21 at a position that the RF electrode is aligned with the glass substrate 60 for depositing the depositing material on the glass surface 64 through the deposition process. Once the depositing material is deposited on the glass surface 64 to form a thin film thereon, the PV module 60′ is formed. Accordingly, the deposition process of the glass substrate 60 is plasma-enhanced chemical vapor deposition (PE-CVD) process. It is worth to mention that the glass substrate 60 is the same as the PV module 60′ that the glass substrate 60 is the panel before the deposition process while the PV module 60′ is the panel after the deposition process. In other words, the PV module 60′ also has the same bottom peripheral edge 61, top peripheral edge 62, two side peripheral edges 63, and two glass surfaces 64.

Accordingly, the deposition room 20 comprises a plurality of dividing walls 22 vertically and spacedly supported in the deposition chamber 21 to define a plurality of deposition compartments 221, wherein each of the dividing walls 22 is sandwiched between two corresponding glass surfaces 64 of the two neighboring glass substrates 60. In other words, when the glass substrate 60 at the vertical orientation is fed into the deposition chamber 21, one of the glass surfaces 64 of the glass substrate 60 is overlapped on one of the side surfaces of the dividing wall 22. Therefore, once the glass substrate 60 is vertically supported in the deposition chamber 21 at the respective deposition compartment 221 and is aligned with the respective dividing walls 22, the depositing material is deposited on the respective glass surface 64 of the glass substrate 60 to form the thin film thereon.

In addition, the step (7) further comprises the following steps.

(7.1) Vacuum the deposition chamber 21 at a predetermined vacuuming threshold.

(7.2) Set the deposition temperature of the deposition chamber 21 at a predetermined temperature threshold.

Once the glass substrate 60 is administered through the deposition process in the deposition chamber 21, the cooling buffer room 40 is moved along the transporting rail 51 to align with the deposition room 20 door-to-door in step (8). Then, the PV module 60′ at the vertical orientation is unloaded from the deposition room 20 to the cooling buffer room 40 in step (9). It is worth to mention that the cooling buffer room 40 is moved to align with the deposition room 20 at the time during the deposition process in step (7) to reduce the manufacturing time of the entire process.

In addition, the deposition room 20 has one accessing gate that the glass substrate 60 is fed into the deposition chamber 21 from the pre-heat room 30 in the step (6) through the accessing gate and the glass substrate 60 is unloaded from the deposition chamber 21 to the cooling buffer room 40 through the same accessing gate.

As it is mention above, the glass substrate 60 is full-automatically transferred through the manufacturing line starting from the cassette 71, the transferring cart 72, the pre-heat room 30, the deposition room 20, to the cooling buffer room 40.

After the step (9), the manufacturing process of the present invention further comprises the following steps.

(10) Automatically shift the glass substrate 60 from the vertical orientation at the cooling buffer room 40 to the horizontal orientation via the robot loading device 10 after the PV module 60′ is cooled down at a predetermined temperature.

(11) Laser scribe the PV module 60′ into a predetermined size and shape.

In order to feed the glass substrate 60 at the vertical orientation between the transferring cart 72, the pre-heat room 30, the deposition room 20, and the cooling buffer 40, the present invention further comprises a substrate transferring device 80 for transferring the glass substrate 60 at the vertical orientation from chamber to another chamber.

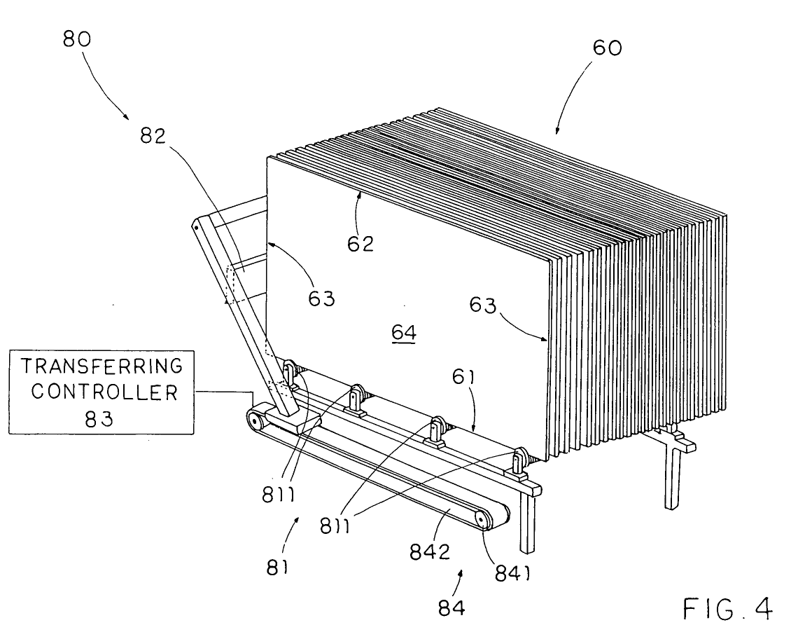

As shown in FIG. 4, the substrate transferring device 80 comprises at least a transferring track 81 provided at each of the transferring cart 72, the pre-heat room 30, the deposition room 20, and the cooling buffer 40, wherein the bottom peripheral edge 61 of the glass substrate 60 is guided to slide along the transferring track 81. The substrate transferring device 80 further comprises a pusher arm 82 and a transferring controller 83 controlling the pusher arm 82 to push at one of the side peripheral edges 63 of the glass substrate 60 so as to slidably push the glass substrate 60 from one chamber to another chamber along the transferring track 81.

It is worth to mention that the top peripheral edge 62 of the glass substrate 60 is guided to slide along another transferring track 81. In other words, the top peripheral edge 62 and the bottom peripheral edge 61 of the glass substrate 60 are guided to slide along the upper transferring track 81 and the lower transferring track 81 respectively.

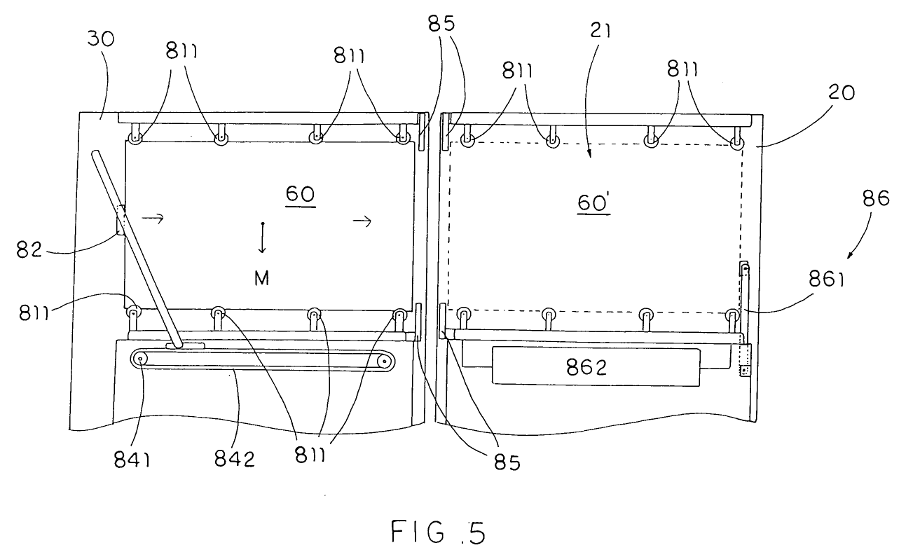

As shown in FIG. 5, when the pre-heat room 30 is aligned with the deposition room 20, the transferring track 81 at the pre-heat room 30 is aligned with the transferring track 81 at the deposition room 20 in an end-to-end manner. In other words, the end of the transferring track 81 at the pre-heat room 30 is aligned with the end of the transferring track 81 at the deposition room 20. Therefore, when the glass substrate 60 is pushed via the pusher arm 82, the glass substrate 60 at the vertical orientation is slidably transferred from the pre-heat room 30 to the deposition room 20 along the transferring tracks 81 thereat.

Accordingly, the pusher arm 82 is extended transversely to engage with one or more glass substrates 60 at the side peripheral edges 63 thereof such that more than one glass substrate 60 can be concurrently fed from the pre-heat room 30 to the deposition room 20 via the movement of the pusher arm 82. In addition, when two or more glass substrates 60 at the vertical orientation are transferred from one chamber to another chamber, two or more spaced apart transferring tracks 81 are provided to transfer the glass substrates 60 at the vertical orientation at the same time.

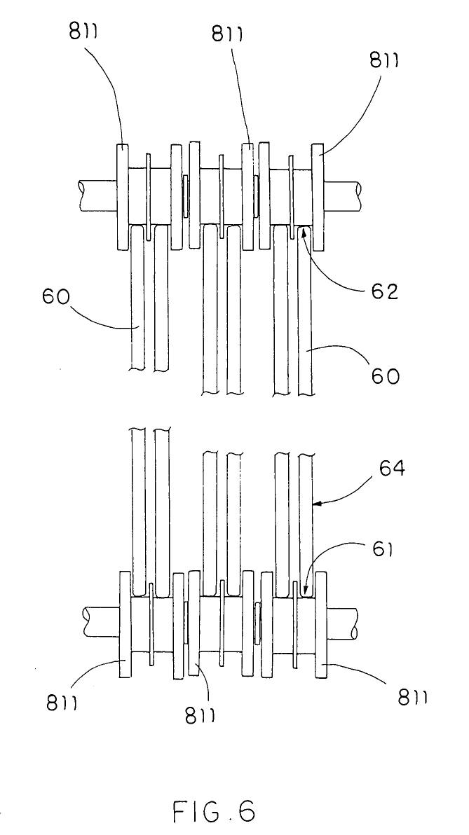

As shown in FIGS. 5 and 6, the transferring track 81 comprises a plurality of transferring rollers 811 spacedly supported in a free rotation manner, wherein the transferring rollers 811 are aligned to form an edge support to support the glass substrate 60 at the bottom peripheral edge 61 thereof. In other words, the transferring rollers 811 are rotated at the same time to transfer the glass substrate 60 at the vertical orientation from one chamber to another chamber. For transferring two or more glass substrates 60, the transferring rollers 811 of the transferring tracks 81 are rotatably coupled along a plurality of supporting axles 812.

As shown in FIG. 6, each of the transferring rollers 811 has a U-shaped cross section defining two guiding walls and a sliding groove therebetween, wherein the bottom peripheral edge 61 of the glass substrate 60 at the vertical orientation is slid along the sliding groove for being transferred. Accordingly, the transferring rollers 811 are aligned to form a sliding platform to support the glass substrate 60 at the bottom peripheral edge 61 thereof.

When the pre-heat room 30 is moved to align with the deposition room 20, a gap between the transferring tracks 81 thereof is formed. Most importantly, the substrate transferring device 80 is arranged to transfer the glass substrate 60 at the vertical orientation across the gap between the two transferring tracks 81. Accordingly, the glass substrate 60 has a center of mass M when the glass substrate 60 is vertically supported. The distance between the center of mass of the glass substrate 60 and the side peripheral edge 63 thereof is longer than the distance between the ends of the two transferring tracks 81 (i.e. the gap between the transferring tracks 81). Therefore, when the glass substrate 60 is pushed to slide from one chamber to another chamber, the glass substrate 60 is stably slid from one transferring track 81 to another transferring track 81 so as to prevent the glass substrate 60 from being drop at the gap between the two transferring track 81.

Likewise, a distance between every two neighboring transferring rollers 811 is shorter that the distance between the center of mass of the glass substrate 60 and the side peripheral edge 63 thereof. Therefore, the glass substrate 60 is adapted to stably slide on the transferring rollers 811.

Accordingly, when the glass substrate 60 is transferred from the pre-heat room 20 to the deposition room 20, the pusher arm 82 at the pre-heat room 30 is controllably operated to push at one of the side peripheral edges 63 of the glass substrate 60 to drive the glass substrate 60 along the transferring track 81 from the pre-heat room 30 to the deposition room 20. In other words, one of the side peripheral edges 63 of the glass substrate 60 is defined as a pushing edge for the pusher arm 82 to engage therewith. Since the transferring track 81 engages with the bottom peripheral edge 63 of the glass substrate 60 and the pusher arm 82 pushes the glass substrate 60 at the side peripheral edge 63, there is no substantial contact with the glass surface 64 of the glass substrate 60 to retain the glass substrate 60 at the upright vertical position so as to prevent any particle dropping on the glass surface 64 of the glass substrate 60 for deposition process.

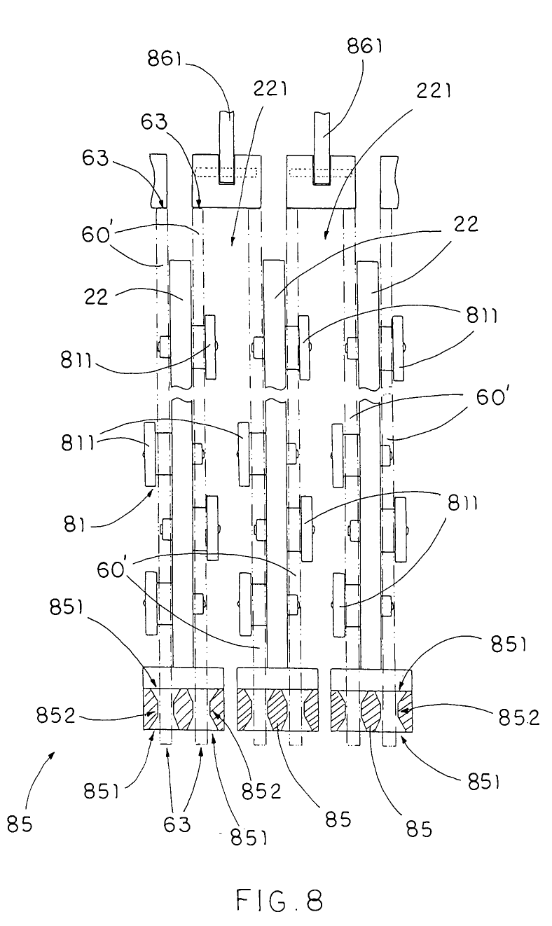

As shown in FIG. 8, the substrate transferring device 80 further comprises at least a feeding guider 85 aligned at an opening end of the transferring track 81 to guide the glass substrate 60 at the vertical orientation being fed into the deposition room 20. As shown in FIG. 8, the feeding guider 85 has two enlarged feeding openings 851 and an elongated feeding slot 852 communicatively extended between the feeding openings 851. Accordingly, the feeding slot 852 is aligned with the transferring track 81, wherein a width of the feeding slot 852 is at least wider than the thickness of the glass substrate 60 such that the glass substrate 60 is slidably transferred to the transferring track 81 through the feeding slot 852 of the feeding guider 85. In addition, a width of each of the feeding openings 851 is gradually reducing towards the feeding slot 852 in such a manner that when the glass substrate 60 is fed to the deposition room 20, the bottom peripheral edge 61 of the glass substrate 60 is firstly guided to slide to the respective feeding opening 851 and is then guided to slide to the feeding slot 852, so as to alignedly slide along the transferring track 81. In other words, if the glass substrate 60 is slightly misaligned with the transferring track 81, the feeding guider 85 is adapted to correct the alignment between the glass substrate 60 and the transferring track 81 to feed the glass substrate 60 along the transferring track 81. Likewise, when the PV module 60′ is fed from the deposition room 20 to the cooling buffer room 40, the bottom peripheral edge 61 of the PV module 60′ is firstly guided to slide to the opposed feeding opening 851 and is then guided to slide to the feeding slot 852. In other words, the first feeding opening 851 of the feeding guider 85 is arranged to adjust the alignment of the glass substrate 60 to be fed in the deposition chamber 20 while the opposed second feeding opening 851 of the feeding guider 85 is arranged to adjust the alignment of the PV module 60′ to be fed out of the deposition chamber 20.

Furthermore, the feeding guider 85 is also provided at each of the pre-heat room 30 and the cooling buffer room 40 to align with the transferring tracks 81 thereat such that the feeding guider 85 is adapted to guide the glass substrate 60 being transferred room to room with precise alignment. Preferably, a pair of feeding guiders 85 are provided to align with the upper transferring track 81 and the lower transferring track 81 respectively at each of the deposition room 20, the pre-heat room 30, and the cooling buffer room 40 to guide the glass substrate 60 or the PV module 60′ from room to room.

As shown in FIG. 6, the substrate transferring device 80 further comprises a driving mechanism 84 controlled by the transferring controller 83 to drive the pusher arm 82 pushing the glass substrate 60. As shown in FIG. 6, the driving mechanism 84 comprises a gear unit 841, an endless gear chain 842 coupling the gear unit 841 with the pusher arm 82, and a motor 843 coupling with the gear unit 841 to drive the pusher arm 82 to move at the loading/unloading direction. Preferably, the pusher arm 82 is moved at a horizontal direction to stably push the glass substrate 60 at the vertical orientation.

It is worth to mention that the transfer of the glass substrate 60 at the vertical orientation between the transferring cart 72 and the pre-heat room 30 in step (4), and between the pre-heat room 30 and the deposition room 40 in step (6), is employed with the same structural configuration of the substrate transferring device 80 such that the manufacturing line of the PV module 60′ can minimize the labor involving thereat to reduce the labor cost of the PV module 60′ while being time effective.

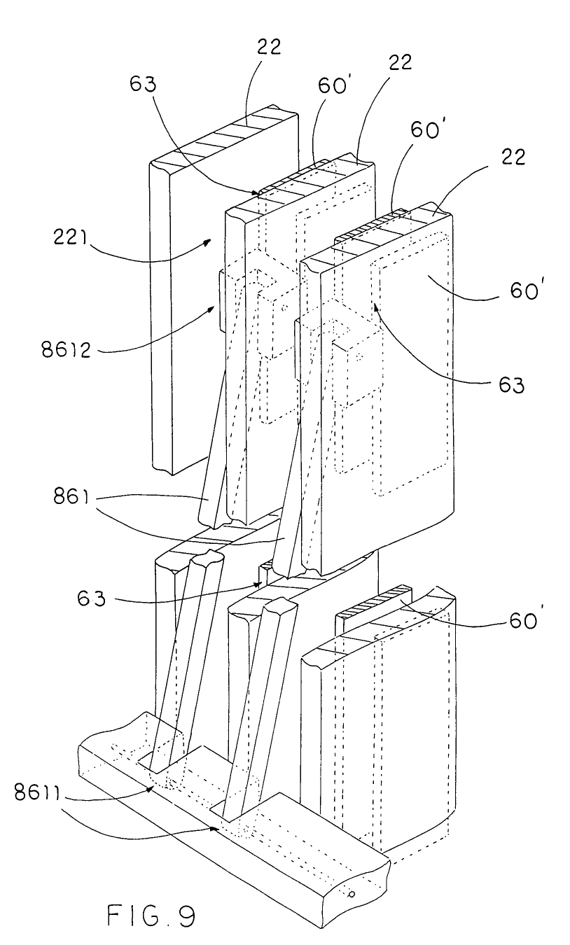

Accordingly, since the dividing walls 22 are provided in the deposition room 20, the pusher arm 82 cannot be incorporated to push the glass substrate 60 out of the deposition room 20. Therefore, the substrate transferring device 80 further comprises transferring system 86 to transfer the PV module 60′ from the deposition room 20 to the cooling buffer room 40. As shown in FIG. 9, the transferring system 86 comprises a pivot arm 861 for pushing the PV module 60′ out of the deposition chamber 21 to the cooling buffer room 40, wherein the pivot arm 861 has a pivot end 8611 pivotally supporting at the deposition chamber 21 and a pushing end 8612 extended at a position that when the pivot arm 861 is pivotally moved from a transverse position to a longitudinal position, the pushing end 8612 of the pivot arm 861 pushes the respective side peripheral edge 63 of the PV module 60′ so as to slidably transfer the PV module 60′ to the cooling buffer room 40. Preferably, the transverse position of the pivot arm 861 is the vertical position.

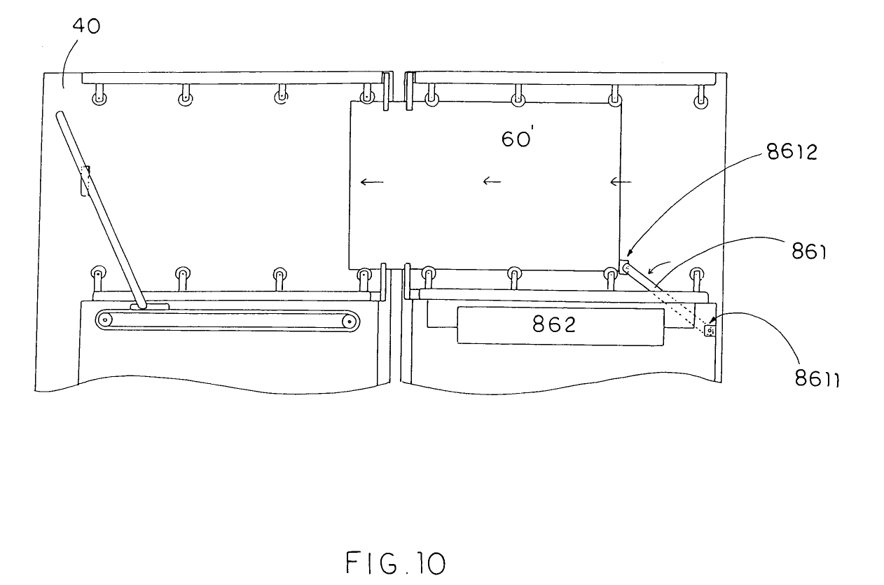

As shown in FIG. 10, a length of the pivot arm 861 should be long enough to push at one of the side peripheral edge 63 of the PV module 60′ until another peripheral edge 63 of the PV module 60′ reaches the transferring track 81 at the cooling buffer room 40. In other words, when the pivot arm 861 is pivotally moved to the longitudinal position, the peripheral edge 63 of the PV module 60′ will engage with the transferring track 81 at the cooling buffer room 40. Therefore, after the PV module 60′ is administered through the deposition process, the pivot arm 861 at the deposition room 20 is controllably operated to push at another side peripheral edge 63 of the PV module 60′ to drive the glass substrate 60 along the transferring track 81 from the deposition room 20 to the cooling buffer room 40. In other words, one of the side peripheral edges 63 of the PV module 60′ is defined as a pushing edge for the pusher arm 82 to engage therewith. It is worth to mention that since the transferring track 81 engages with the bottom peripheral edge 63 of the PV module 60′ and the pusher arm 82 pushes the PV module 60′ at the side peripheral edge 63, there is no substantial contact with the glass surface 64 of the PV module 60′ to retain the PV module 60′ at the upright vertical position so as to prevent any particle dropping on the glass surface 64 of the PV module 60′ after deposition process.

For concurrently transferring two or more PV modules 60′ from the deposition chamber 21 to the cooling buffer room 40, two or more pivot arms 861 are concurrently moved to push at the side peripheral edges 63 of the PV modules 60′ so as to slidably transfer the PV modules 60′ to the cooling buffer room 40.

As it is mentioned above, the transferring rollers 811 are spacedly supported to form the transferring track 81 within the deposition chamber 21. The transferring system 86 further comprises a driving motor 862 driving the pivot arm 861 to pivotally move and driving the transferring rollers 811 to rotate. In other words, the pusher arm 82 pushes at the side peripheral edge 63 of the PV module 60′ while the transferring rollers 811 are rotated to drive the PV module 60′ at the bottom peripheral edge 61 thereof to transfer the PV module 60′ to the cooling buffer room 40. Therefore, at the initial transferring process, the PV module 60′ is slidably guided by the pivot arm 861 to push at the side peripheral edge 63 and via the transferring rollers 811 by the self-rotational movement thereof. Once the pivot arm 861 is pivotally moved to the longitudinal position that the peripheral edge 63 of the PV module 60′ engages with the transferring track 81 at the cooling buffer room 40, the PV module 60′ will be transferred only via the transferring rollers 811 by the self-rotational movement thereof.

Before the step (7), the present invention further comprises a step of retaining the temperature of the RF electrode in the deposition chamber 21 of the deposition room 20 such that when the glass substrate 60 at the vertical orientation is guided into the deposition chamber 21 to align with the RF electrode, the glass substrate 60 can be administered through the deposition process to reduce the time of pre-heating the RF electrode. In order to reduce the time of the manufacturing process, the RF electrode is pre-heated within the deposition chamber 21 at the same time when the glass substrate 60 is pre-heated in the pre-heat room 30 and is transferred to the deposition room 20. Therefore, at the time when the glass substrate 60 is transferred to the deposition chamber 21, the deposition process of the glass substrate 60 can start instantly.

Accordingly, the RF electrode is stationary supported within the deposition chamber 21 such that the operator does not need to transport the RF electrode with the glass substrate together in comparison with the convention manufacturing process. In order to retain the temperature of the RF electrode in the deposition chamber 21, the deposition room 20 comprises a heat source pre-heating the RF electrode in the deposition chamber 21.

According to the preferred embodiment, a plurality of glass substrates 60 can be automatically transferred back and forth through the manufacturing line of the process at the same time to speed up the entire process and to reduce the labor cost thereof. In other words, the glass substrates 60 are automatically shifted from the horizontal orientation to the vertical orientation via the robot loading device 10 and automatically transferred between two different chambers.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method of manufacturing thin-film-base PV module, comprising the steps of:
(a) loading one or more glass substrates into a stationary deposition chamber in a standing manner along one or more transferring tracks provided in said deposition chamber, wherein each of said glass substrates has two side peripheral edges and a bottom peripheral edge guided along said transferring track;
(b) administering said glass substrate through a deposition process within said deposition chamber to form one or more PV modules; and
(c) unloading said PV module from said deposition chamber in a standing manner along said transferring track.

2. The method, as recited in claim 1, wherein the step (a) further comprises a step of alignedly guiding said glass substrates to engage with said transferring track.

3. The method, as recited in claim 2, wherein a feeding guider is aligned at an opening end of said transferring track to guide said glass substrate being fed into said deposition chamber, wherein said feeding guider two enlarged feeding openings and an elongated feeding slot which is communicatively extended between said feeding openings and is arranged when said glass substrate is fed into said deposition chamber, said bottom peripheral edge of said glass substrate is guided to slide to said respective feeding opening and is then guided to slide to said feeding slot so as to alignedly guide said bottom peripheral edge of said glass substrate to engage with said transferring track, and when said PV module is unloaded from said deposition chamber, said bottom peripheral edge of said PV module is guided to slide to another said feeding opening and is then guided to slide to said feeding slot.

4. The method, as recited in claim 3, wherein a width of said feeding slot is at least wider than a thickness of said glass substrate, and a width of each of said feeding openings is gradually reducing towards said feeding slot.

5. The method, as recited in claim 1, wherein said transferring track is formed by spacedly and alignedly providing a plurality of transferring rollers, wherein each of said transferring rollers is rotated to support said glass substrate at said bottom peripheral edge; and

6. The method, as recited in claim 5, wherein the distance between every two said neighboring transferring rollers is shorter that the distance between the center of mass of said glass substrate and said side peripheral edge thereof so as to stably support said vertical glass substrate when said bottom peripheral edge of said glass substrate slides at said transferring rollers.

7. The method, as recited in claim 6, wherein each of said transferring rollers has a U-shaped cross section defining two guiding walls and a sliding groove therebetween, wherein said bottom peripheral edge of said vertical glass substrate is slid along said sliding groove of each of said transferring roller for being transferred.

8. The method, as recited in claim 5, wherein said transferring rollers are powered by a driving motor to drive said transferring roller to rotate so as to load said glass substrate into said deposition chamber and to unload said PV module from said deposition chamber.

9. The method, as recited in claim 7, wherein said transferring rollers are powered by a driving motor to drive said transferring roller to rotate so as to load said glass substrate into said deposition chamber and to unload said PV module from said deposition chamber.

10. The method, as recited in claim 5, wherein the step (c) further comprises the steps of:
(c.1) providing a pivot arm having a pivot end pivotally supported at said deposition chamber and a pushing end extended towards said respective side peripheral edge of said PV module; and
(c.2) pivotally moving said pivot arm from a transverse position to a longitudinal position such that said pushing end of said pivot arm pushes said the respective side peripheral edge of said PV module out of said deposition chamber.

11. The method, as recited in claim 9, wherein the step (c) further comprises the steps of:
(c.1) providing a pivot arm having a pivot end pivotally supported at said deposition chamber and a pushing end extended towards said respective side peripheral edge of said PV module; and
(c.2) pivotally moving said pivot arm from a transverse position to a longitudinal position such that said pushing end of said pivot arm pushes said the respective side peripheral edge of said PV module out of said deposition chamber.

12. The method as recited in claim 1 wherein, in the step (a), said glass substrates are concurrently loaded into said deposition chamber by pushing said side peripheral edges of said glass substrates into said deposition chamber.

13. The method as recited in claim 11 wherein, in the step (a), said glass substrates are concurrently loaded into said deposition chamber by pushing said side peripheral edges of said glass substrates into said deposition chamber.

14. The method as recited in claim 1 wherein, before the step (a), further comprises the step of:
retaining said glass substrate in a standing manner in a first chamber at a position that said bottom peripheral edge of said glass substrate is supported along said transferring track in said first chamber; and
moving said first chamber to line up with said deposition chamber at a position that said transferring track at said first chamber is aligned with said transferring track at said deposition chamber in an end-to-end manner such that said glass substrate is adapted to be loaded from said first chamber to said deposition chamber through said transferring tracks.

15. The method, as recited in claim 14, wherein the distance between two corresponding ends of said transferring tracks at said two different chambers is shorter than the distance between the center of mass of said glass substrate and said corresponding side peripheral edge thereof such that said glass substrate is stably slid from one of said transferring tracks to another said transferring track to transfer said glass substrate from one chamber to another chamber.

16. The method, as recited in claim 14, wherein said first chamber is a pre-heat room that said glass substrate is pre-heated in said pre-heat room before said glass substrate is transferred to said deposition chamber.

17. The method, as recited in claim 16, further comprising a step of automatically shifting said glass substrate from its horizontal orientation to a standing manner via a robot loading device to retain said glass substrate at a standing manner before said glass substrate is loaded in said first chamber.

18. The method, as recited in claim 1, wherein the step (c) further comprises the step of:
(c.1) moving a second chamber to line up with said deposition chamber at a position that said transferring track at said deposition chamber is aligned with said transferring track at said second chamber in an end-to-end manner; and
(c.2) guiding said side peripheral edges of said PV module from said deposition chamber to said second chamber.

19. The method, as recited in claim 18, wherein said second chamber is a cooling buffer room.

20. The method, as recited in claim 1, wherein said glass substrate is loaded in said deposition chamber through an accessing gate thereof and said PV module is unloaded from said deposition chamber through said accessing gate.

21. The method, as recited in claim 1, wherein the step (b) further comprises the steps of:
(b.1) stationary mounting a RF electrode in said deposition chamber at a position that when said glass substrate is fed into said deposition chamber, said RF electrode is aligned with said glass substrate; and
(b.2) pre-heating said RF electrode in said deposition chamber before said deposition process.

22. A process of manufacturing thin-film-base PV module, comprising the steps of:
(a) moving a pre-heat room to line up with a stationary deposition room along a transporting rail, wherein one or more glass substrates, having a bottom peripheral edge and two side peripheral edges, is supported in said pre-heat room at a standing manner for being pre-heated;
(b) concurrently transferring said glass substrates from said pre-heat room to said deposition room, wherein said pre-heat room is moved back to an original position along said transporting rail after said glass substrate is transferred to said deposition room;
(c) administering said glass substrates through a deposition process within a deposition chamber of said deposition room to form PV modules at a standing manner;
(d) moving a cooling buffer room to line up with said deposition room along said transporting rail; and
(e) transferring said PV modules from said deposition room to said cooling buffer room.

23. The process, as recited in claim 22, wherein the step (a) comprises the steps of:
(a.1) aligning first transferring tracks at said pre-heat room with second transferring tracks at said deposition room in an end-to-end manner, wherein said bottom peripheral edges of said glass substrates are supported along said first transferring tracks to retain said glass substrates in a standing manner; and
(a.2) pushing said side peripheral edges of glass substrates to slidably transfer said glass substrates from said first transferring tracks to said second transferring tracks so as to transfer said glass substrates from said pre-heat room to said deposition room.

24. The process, as recited in claim 22, wherein the step (e) comprises the steps of:
(e.1) aligning second transferring tracks at said deposition room with third transferring tracks at said cooling buffer room in an end-to-end manner, wherein said bottom peripheral edges of said PV modules are supported along said second transferring tracks to retain said PV module in a standing manner; and
(e.2) pushing said side peripheral edges of said PV modules to slidably transfer said PV module from said second transferring tracks to said third transferring tracks so as to currently transfer said PV modules from said deposition room to said cooling buffer room.

25. The process, as recited in claim 24, wherein the distance between two corresponding ends of said transferring tracks at said two different chambers is shorter than the distance between the center of mass of said glass substrate and said corresponding side peripheral edge thereof such that said glass substrate is stably slid from one of said transferring tracks to another said transferring track to transfer said glass substrate from one chamber to another chamber.

26. The process, as recited in claim 25, wherein each of said transferring tracks comprises a plurality of transferring rollers spacedly and alignedly supported at a free-rotating manner to support said bottom peripheral edge of said glass substrate, wherein the distance between every two said neighboring transferring rollers is shorter that the distance between the center of mass of said glass substrate and said side peripheral edge thereof so as to stably support said glass substrate in a standing manner when said bottom peripheral edges of said glass substrates slide at said transferring rollers.

27. The process, as recited in claim 26, wherein each of said transferring rollers has a U-shaped cross section defining two guiding walls and a sliding groove therebetween, wherein said bottom peripheral edge of said glass substrate is slid along said sliding groove of each of said transferring rollers for being transferred.

28. The process, as recited in claim 22, wherein said deposition room is stationary located between said pre-heat room and said cooling buffer room at a position adjacent to said transporting rail such that each of said pre-heat room and said cooling buffer room is controllably moved to line up with said deposition room along said transporting rail.

29. The process, as recited in claim 22, wherein the step (c) further comprises the steps of:
(c.1) stationary mounting a plurality of RF electrodes in a deposition chamber of said deposition room at a position that when said glass substrates are fed into said deposition chamber, said RF electrodes are aligned with said glass substrates; and
(c.2) pre-heating said RF electrodes in said deposition chamber before said deposition process.
